(19) United States
(12) Patent Application Publication
(10) Pub. No.: US 2011/0290302 A1
(43) Pub. Date: Dec. 1, 2011

(54) Rugged concentrating hybrid solar energy module

(76) Inventor: Yi Pang, Olney, MD (US)

(21) Appl. No.: 13/192,742

(22) Filed: Jul. 28, 2011

Related U.S. Application Data
(63) Continuation-in-part of application No. 12/773,994, filed on May 5, 2010.
(60) Provisional application No. 61/315,057, filed on Mar. 18, 2010.
(60) Provisional application No. 61/368,270, filed on Jul. 28, 2010.

(51) Int. Cl. H01L 31/058; F24J 2/12; F24J 2/24

(52) U.S. Cl. 136/248; 126/651; 126/694

(57) ABSTRACT

A solar energy module includes a casing, a mirror, a transparent top, a pipe, a fluid within the pipe and photovoltaic cells. The casing has three walls including two end walls and one wall in the form of an elongated U-shaped structure. The mirror is parabolic and sits atop the bottom wall of the casing to produce a line focus within the casing. The transparent top closes the casing to form an air-tight enclosure. The pipe has flat walls and is positioned at the line focus. The flat walls are at least a top-facing planar wall and a bottom-facing planar wall. The photovoltaic cells are attached at least to the bottom-facing planar wall. The fluid is confined within the pipe and carries away the heat from the photovoltaic cells. The air-tight module is optionally holding a vacuum and/or contains inert gas.

### CROSS-REFERENCE TO RELATED APPLICATIONS

This application is a continuation-in-part of pending U.S. application Ser. No. 12/773,994, filed 05 May 2010, which claims the benefit of U.S. Provisional application 61/315,057 filed 18 Mar. 2010, both of which are hereby incorporated by reference herein. This application additionally claims the benefit of U.S. Provisional Application No. 61/368,270, filed 28 Jul. 2010, which is hereby incorporated by reference herein.

### TECHNICAL FIELD

In the field of photoelectrics, a photovoltaic device for the generation of an electric and thermal energy upon exposure to light, by the direct conversion of the light to electrical energy, uses an arrangement of photoelectric cells with a concentrator, and heat extraction means.

### BACKGROUND ART

The present invention is distinguished from the prior art by a structure that seeks to simultaneously serve principles to enable the device to inexpensively convert sunlight to electricity and thermal energy by (1) obtaining a higher concentration of sunlight to reduce the amount of expensive photovoltaic cells; (2) adjusting the location of the photovoltaic surface to maximize the efficiency of the photovoltaic cell by concentrating light more or less uniformly in intensity across its surface and by enabling light to strike the surface of the photovoltaic cell as close as possible to normal to its surface; (3) using almost all light incident on photovoltaic cells for thermal and electric energy production, with the understanding that since thermal energy is considered as lower-grade energy source, the preference is to maximize production of electric power; (4) making the module rugged to withstand harsh environments and adverse weather conditions; and (5) using inexpensive and light weight and/or less material to reduce the system weight and cost simultaneously.

The prior art is uniform in the failure to describe a solar energy device structure that has the potential to implement the above principles. For example, use of a tube with a concentrator for a solar energy assembly is disclosed in U.S. Pat. No. 4,144,095 (the '095patent). The '095 patent teaches a hermetically sealed tube with a trough shaped radiation reflector concentrating light on a solar cell and rotation of the assembly to follow the sun. It further teaches that a cooling fluid or inert gas may be circulated through the envelope in order to control the temperature inside the tube. The structure of the device taught in the '095 patent cannot simultaneously satisfy principles, noted above. Other more sophisticated prior art designs involve secondary optics in order to satisfy the five principles noted above.

The present invention is distinct from the '095 patent and other prior art in this field in that it includes a structure using a pipe with a plurality of planar walls within a sealed vessel amenable to easy assembly in meeting these five principles without secondary optics.

### SUMMARY OF INVENTION

A solar energy module includes a casing, a mirror, a transparent top, a pipe, a fluid within the pipe and photovoltaic cells.

The casing, much like a rain gutter on a house, has three walls including two end walls and one wall in the form of an elongated U-shaped structure. The U-shaped structure is a unit formed of a continuous integral material and having a bottom wall and two vertical side walls extending upwardly from the bottom wall to form an open top to the casing.

The mirror is parabolic and sits atop the bottom wall of the U-shaped structure to focus light along a line above the bottom wall and parallel to the longitudinal axis and within the casing.

The transparent top is attached at the open top of the U-shaped structure to form an air-tight enclosure within the casing. The transparent top is preferably flat but may have a curved shape for enhanced rigidity and other purposes. The transparent top may have an anti-reflective coating.

The pipe goes from end to end of the U-shaped structure, has flat walls and is positioned at the mirror line focus. The flat walls are at least a top-facing planar wall and a bottom-facing planar wall. The bottom-facing planar wall is positioned to receive reflected light from the mirror and the top-facing planar wall is positioned to receive direct sunlight through the transparent top. The pipe may be a heat pipe to take away the heat from the photovoltaic cells.

The photovoltaic cells are attached to the bottom-facing planar wall and preferable to each of the flat walls of the pipe where light can be captured.

The fluid is confined within the pipe, has a low vapor point so that it evaporates and carries away the heat from the photovoltaic cells.

The air-tight module is optionally holding a vacuum and/or contains inert gas at or below atmospheric pressure. These optional physical conditions prevent heat loss to environment and protect against the deleterious effects of oxidation.

The casing's continuous integral material may be a single material, such as metal or composite material, such as fiber reinforced polymer.

The casing's continuous integral material may be a made into thin sheet stamped with patterns of ridges, grooves or corrugations to reinforce its structural rigidity, This configuration is both rigid and lightweight. It is also inexpensive to produce and the material cost is significantly reduced.

The casing's bottom wall may also have a parabolic cross-sectional shape to correspond to the mirror. This configuration utilizes the casing as the mirror support, thus vastly simplifying the structure and cost.

### Technical Problem

Existing solar photovoltaic, concentrating photovoltaic, or concentrating photovoltaic and thermal combination devices suffer from being fragile, bulky, heavy, inefficient, having high manufacturing cost, or having insufficient modularity to enable application versatility.

The efficiency of a photovoltaic cell in producing power is dependent on the amount of sunlight impinging on the cell and its steady state temperature. The efficiency generally decreases at higher operating temperatures. Thus, there is room for improvement over the prior art when more sunlight can be concentrated on the solar cell while at the same time without increasing its operating temperature significantly and extracting the thermal energy for hot water or space heating. When combined with a rugged design, the modularity of the present module offers a lower manufacturing cost than found in other designs.

Most solar concentrator technology on the market typically results in higher cost and is generally not amenable to production in modular systems. The large-scale construction usually required for solar concentrators and the consequent large scale and the significant size of cooling systems have made concentrator photovoltaic systems uneconomical for most applications.

To maximize current state of the art solar cell efficiency, the optical system should be constrained so that light impinges on photovoltaic cells as uniformly as possible and as normal to the cell surface as possible. A pipe with multiple flat surfaces enables maximizing cell exposure and thus electricity and heat production. Currently most of the concentrator photovoltaic and concentrator photovoltaic thermal devices do not adhere to these constraints, and consequently suffer from lower optical efficiency.

### Solution to Problem

The solution to the problem is a unique hybrid system that maximizes electricity and heat production from incident solar radiation by using an air-tight vessel with a transparent top. The vessel contains a concentrator and solar cells mounted to a structured, flat-walled pipe, which efficiently extracts heat using a low vapor point coolant within the pipe.

### Advantageous Effects of Invention

The present invention offers a rugged and low manufacturing cost module. The module is highly efficient and can be easily assembled into an array for almost any application. The module can maximally produce electricity from incident solar radiation using solar cells mounted on multiple flat surfaces on a pipe within a vessel. The module simultaneously produces useful heat energy by efficiently extracting energy otherwise wasted or contributing to system inefficiencies. Its unique structure enables the optimal optical efficiency in which light is concentrated on multiple photovoltaic cells.

By utilizing separate and different materials for the transparent top and the casing, there is a diversity of choices of materials that minimizing component thickness and satisfy the principles of 1) module rigidity, 2) using light weight components, and 3) achieving lower cost, both in material and manufacturing by utilizing pressing and stamping.

### BRIEF DESCRIPTION OF DRAWINGS

The drawings illustrate preferred embodiments of the solar energy hybrid module according to the invention and the reference numbers in the drawings are used consistently throughout. New reference numbers in FIG. 2 are given the 200 series numbers. Similarly, new reference numbers in each succeeding drawing are given a corresponding series number beginning with the figure number.

FIG. 1 is a sectional view of a preferred module with a flat transparent top.

FIG. 2 is a sectional view of the casing in the module shown in FIG. 1.

FIG. 3 is a sectional view of the pipe in the module shown in FIG. 1.

FIG. 4 is sectional view of a square pipe.

FIG. 5 is a perspective of a vertical side wall.

FIG. 6 is a perspective of a module with a transparent top formed with a curved shape.

FIG. 7 is a perspective of a module shown with an anti-reflective coating on the transparent top and a casing with ridges and grooves.

### DESCRIPTION OF EMBODIMENTS

In the following description, reference is made to the accompanying drawings, which form a part hereof and which illustrate several embodiments of the present invention. The drawings and the preferred embodiments of the invention are presented with the understanding that the present invention is susceptible of embodiments in many different forms and, therefore, other embodiments may be utilized and structural, and operational changes may be made, without departing from the scope of the present invention.

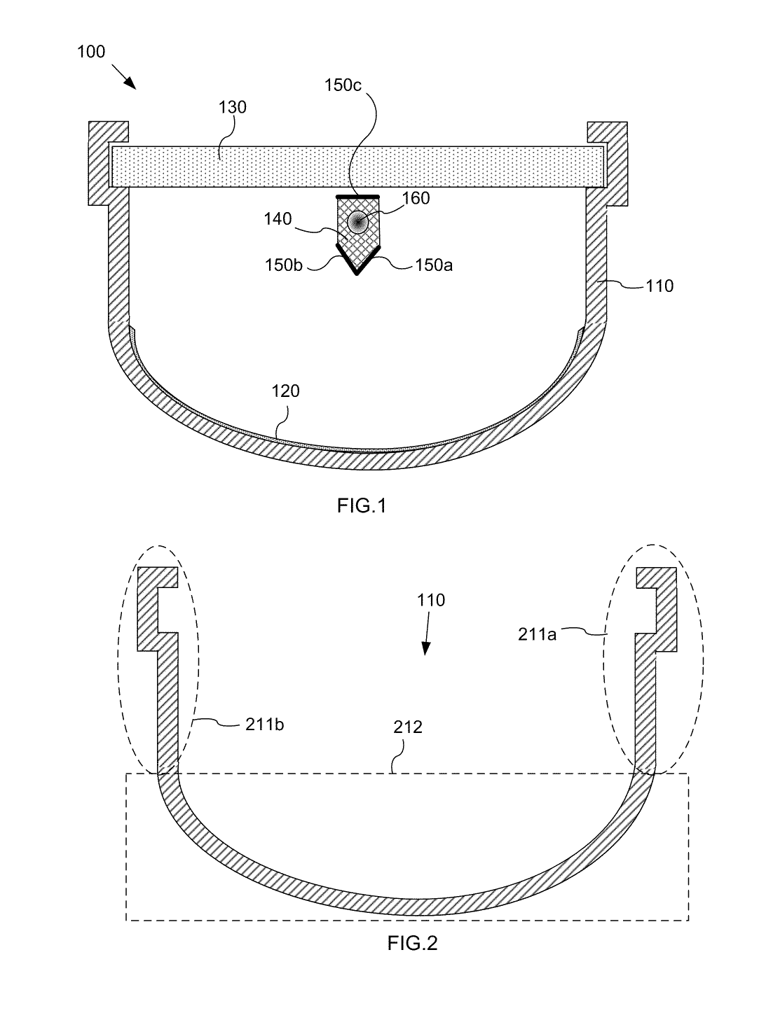

FIG. 1 illustrates a preferred embodiment of the solar energy hybrid module for extracting electricity and heat upon exposure to light. The module (100) includes a casing (110), a mirror (120), a transparent top (130), a pipe (140), first bottom-facing photovoltaic cells (150a), second bottom-facing photovoltaic cells (150b), top-facing photovoltaic cells (150c), and a fluid (160) within the pipe (140).

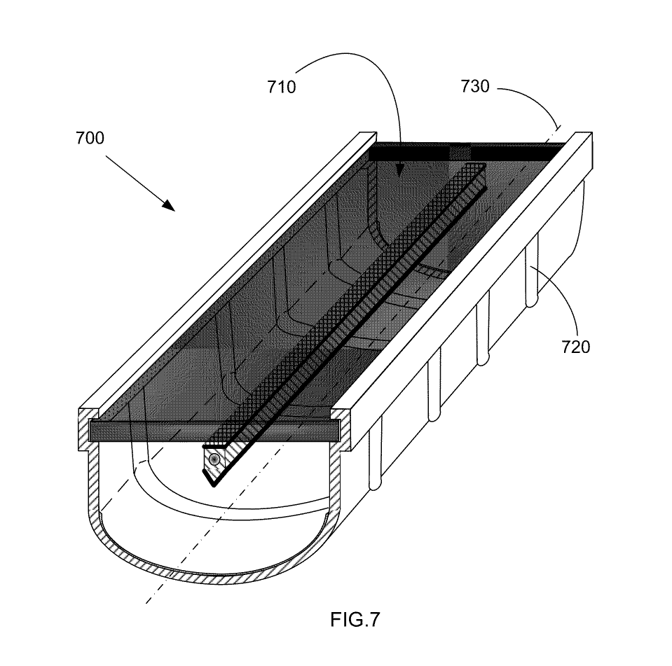

FIG. 2 illustrates the casing (110) cross-section. The casing (110) generally has a U-shape in cross-section and in perspective is comparable in shape to a rain gutter commonly found at the edge of a roof. FIG. 7 shows the U-shape in perspective. The U-shape is a very loose description of the cross-sectional shape of the elongated U-shaped structure. The bottom wall may be curved as in the U-shape or it may be flat or have another cross-sectional shape.

The casing (110) is elongated and necessarily, therefore, has a longitudinal axis (730). The casing (110) is in three parts. The first part is an elongated U-shaped structure and the remaining two parts are two vertical end-walls. FIG. 5 illustrates a vertical end-wall (500). The two vertical end-walls close up the ends of the elongated U-shaped structure. At least one vertical end-wall (500) defines an opening (510) leading out of the casing (110). The opening provides an exit port for the fluid (160) in the pipe (140) to exit the casing (110). Transport of the fluid (160) out of the casing (110) is the means for cooling the photovoltaic cells and delivering a source of heat that may be used by other conventional means or simply dissipated.

The U-shape part of the casing (110) has three walls formed of a continuous integral material as shown within the dashed enclosures in FIG. 2. Examples of a continuous integral material include a metal, such as aluminum, tin or copper; polymer; plastic; and a composite such as galvanized steel or fiber reinforce polymer.

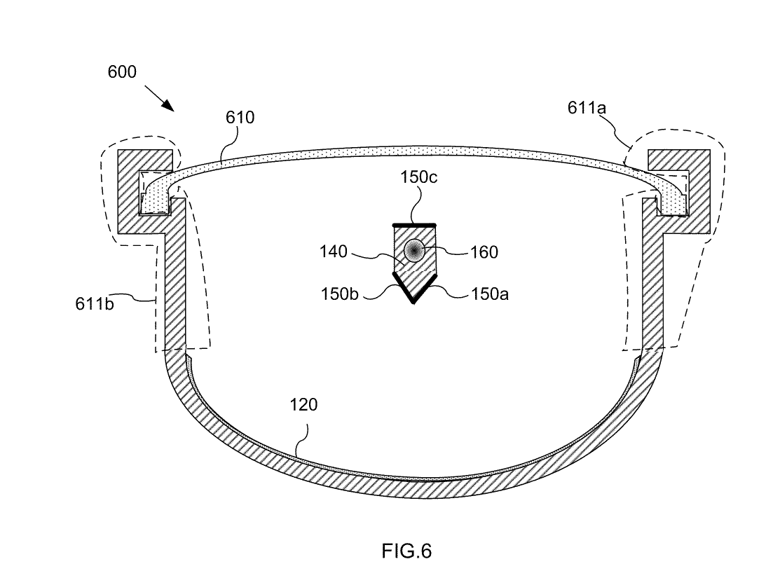

These three walls are a right vertical-side-wall (211a), a left vertical-side-wall (211b) and a bottom wall (212). The two vertical side walls extend upwardly to define an open top to the casing (110). The topmost extremity of each vertical-side-wall preferably forms an inwardly-facing channel to accept the transparent top (130) in a slidable engagement with the casing (110). A bolted or clamping engagement with the casing (110) may also be employed. Gasket material, sealant or glue may be used to seal the transparent top (130) within the channels. Variations on this engagement are possible. For example, FIG. 6 shows an alternative configuration module (600) to accept a curved transparent-top (610), that is, a transparent top with a curved shape. As is shown, a FIG. 6 right vertical-side-wall (611a) and a FIG. 6 left vertical-side-wall (611b) have a channel that permits the curved transparent-top (610) to slidably engage the casing (600) and provide rigidity when the casing (600) is evacuated.

The mirror (120) preferably has a parabolic cross-sectional shape and is installed atop or adjacent to the bottom wall (212). The mirror (120) creates a line-focus as would any elongated reflector having a parabolic cross-sectional shape. In the first alternative module (700) shown in FIG. 7, the line-focus is parallel to the longitudinal axis (730) and within the casing, that is, below the bottom of the transparent top (130). The mirror (120) may be a reflecting coating or a reflecting sheet attached to the bottom wall (212) when the bottom wall (212) also has a parabolic cross-sectional shape.

The transparent top (130) is attached at the open top of the U-shaped structure to form an air-tight enclosure within the casing (110). The transparent top (130) is preferably flat but may have a curved shape for enhanced rigidity and other purposes. For example, if the casing (110) is held at a pressure lower than atmospheric pressure, the transparent top is preferred made with a curved shape to enhance its rigidity. A curved transparent-top (610) is shown in FIG. 6. The transparent top may have an anti-reflective coating (710), which minimizes loss of light entering the casing (110). The transparent top (130) is preferably glass, which is a durable material. Acrylic material may also be an alternative transparent material, which is lighter than glass and less prone to fracture under impact. Other transparent plastic material may also be used.

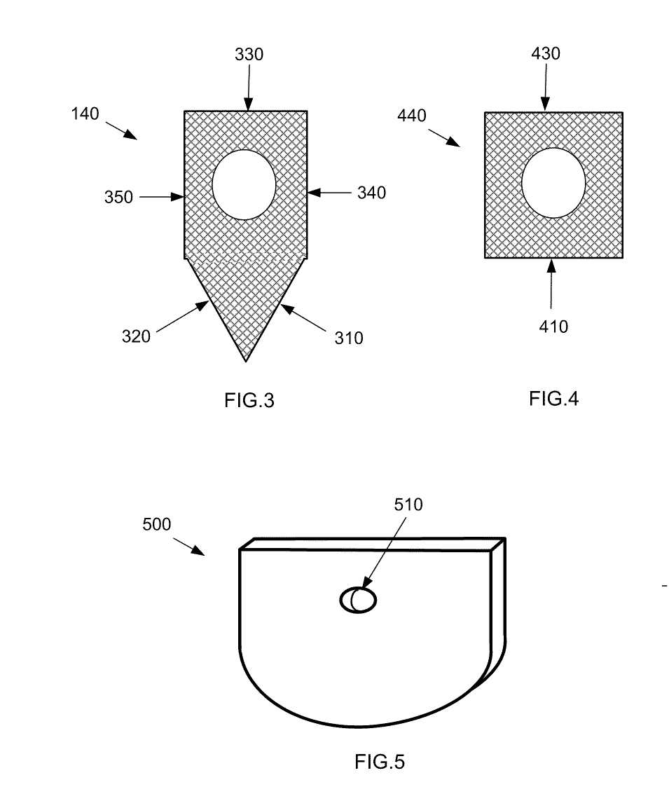

The pipe (140) goes from end to end of the U-shaped structure parallel to the longitudinal axis. The pipe (140) is flowably connected out of the casing through a vertical end-wall (500). This vertical end-wall (500) defines an opening (510) leading out of the casing. The pipe (140) has a polygon cross-sectional shaped because it has at least three flat walls, also known as planar walls. The term “flat wall” is herein used interchangeably with the term “planar wall.” Each bottom-facing planar wall is located at or near the line-focus to receive reflected sunlight from the mirror (120). Preferably, the pipe (140) has five flat or planar walls as is illustrated in FIG. 3: a first bottom-facing planar wall (310); a second bottom-facing planar wall (320); a top-facing planar wall (330); a right-side-facing-planar-wall (340); and a left-side-facing-planar-wall (350). Since the right-side-facing-planar-wall (340) and left-side-facing-planar-wall (350) do not receive direct or reflected light, they typically would not have photovoltaic cells placed on their surface.

FIG. 4 illustrates a second pipe (440) with fewer planar walls. Second pipe (440) has a FIG. 4 top-facing planar wall (430) and a FIG. 4 bottom-facing planar wall (410). The FIG. 4 bottom-facing planar wall (410) is positioned to receive reflected light from the mirror (120). The FIG. 4 top-facing planar wall (430) is positioned to receive direct sunlight through the transparent top.

The pipe (140) or the second pipe (440) may be a heat pipe, which is well known as a device to enable heat-transfer using thermal conductivity and phase transition. The pipe material conducts heat away from the photovoltaic cells to the fluid (160) within.

The fluid (160) is a coolant, which is preferably a liquid in contact with a thermally conductive solid surface of the pipe material. The fluid (160) is confined within the pipe (140) and preferably has a low boiling point, also known as a vapor point, so that the fluid readily evaporates and carries away the heat from the photovoltaic cells. By low boiling point, it is reference to the operating temperature of the photovoltaic cells. The preferably choices of such coolants are water with antifreeze, alcohol, and acetone. The preferable choices of the coolants may also need to compatible with the pipe material.

The fluid (160) vaporizes by absorbing heat from the pipe material. The vapor is allowed to exit the casing (110) where it condenses back into a liquid at a cold interface capturing the latent heat in the vapor. The liquid then returns to the pipe (140) within the casing (110) either through capillary action or by force of gravity to repeat the cycle. Another configuration requires two openings in the casing (110) for entrance and exit of the coolant to permit cycling the fluid (160) within a closed loop.

Photovoltaic cells are attached to the bottom wall (212) such that they are uniformly illuminated on the bottom surfaces of the pipe (140). The photovoltaic cells are attached preferably to each of the flat walls of the pipe (140) where light can be captured and turned into electricity. This is illustrated in FIG. 1 and FIG. 3, where first bottom-facing photovoltaic cells (150a) are attached to the first bottom-facing planar wall (310); second bottom-facing photovoltaic cells (150b) are attached to the second bottom-facing planar wall (320); and top-facing photovoltaic cells (150c) are attached to top-facing planar wall (330). The top-facing photovoltaic cells (150c), which are attached to the top-facing planar wall (330) are intended to receive direct sunlight. The bottom facing flat walls are intended to receive sunlight reflected from the mirror (120). FIG. 4 illustrates an embodiment with one FIG. 4 bottom-facing planar wall (410) and one FIG. 4 top-facing planar wall (430). The photovoltaic cells are preferably made of monocrystalline silicon, but many different photovoltaic cells are now commercially available. An alternative configuration omits the top-facing photovoltaic cells (150c) to further reduce cost without significantly reducing the electricity output or efficiency.

The module (100) is air-tight. The casing (11) is optionally holding a vacuum and/or contains inert gas, such as krypton. Holding a vacuum and/or adding inert gas to the casing (110) improves thermal insulation, displaces moisture within the casing and protects the photovoltaic cells and mirror surface from oxidation. Holding a vacuum will provide better thermal insulation, but is technically and structurally more demanding.

The continuous integral material of the elongated U-shaped structure of the casing (110) may be single material, or a composite material. An example of a single material includes a sheet material, such as thin sheet metal. An example of a composite material is a thin fiber reinforced polymer sheet. Either may be stamped with ridges and grooves (720), or corrugations to improve module rigidity. By using this configuration, both the weight and cost are reduced without sacrificing the structural rigidity.

The bottom wall (212) of the casing (110) may also have a parabolic cross-sectional shape to correspond to the mirror (120). This bottom wall then serves as the support for the mirror, thus greatly simplifying the structure and reducing the cost.

The above-described embodiments including the drawings are examples of the invention and merely provide illustrations of the invention. Other embodiments will be obvious to those skilled in the art. Thus, the scope of the invention is determined by the appended claims and their legal equivalents rather than by the examples given.

### INDUSTRIAL APPLICABILITY

The invention has application to the energy industry.

What is claimed is:

1. A module for extracting electricity and heat upon exposure to light, the module comprising:
a casing having a longitudinal axis defined by:
three walls formed of a continuous integral material, the three walls comprising:
two vertical side walls extending upwardly to define an open top to the casing; and
a bottom wall; and
two vertical side-end-walls at extremities of the longitudinal axis;
a mirror atop the bottom wall, the mirror creating a line-focus, the mirror having a parabolic cross-sectional shape, the line-focus being parallel to the longitudinal axis and within the casing;
a transparent top attached at the open top to form an air-tight enclosure within the casing;
a pipe positioned parallel to the longitudinal axis and flowably connected out of the casing through at least one of the two vertical end-walls;
the pipe having a cross-sectional shape formed by a plurality of planar walls, the plurality of planar walls comprising;
a top-facing planar wall positioned to receive direct sunlight through the transparent top;
a bottom-facing planar wall located at or near the line-focus to receive reflected sunlight from the mirror;
a plurality of photovoltaic cells attached to the bottom-facing planar wall;
a fluid having a low vapor point, the fluid confined within the pipe and adapted to use phase transition to remove heat from the plurality of photovoltaic cells.

2. The module according to claim 1, wherein the air-tight enclosure is held at a pressure less than atmospheric pressure.

3. The module according to claim 1, wherein the air-tight enclosure is contains inert gas.

4. The module according to claim 1, wherein the continuous integral material comprises sheet material stamped with ridges and grooves.

5. The module according to claim 1, wherein the continuous integral material is selected from the group consisting of single material, and composite material.

6. The module according to claim 1, wherein the bottom wall has a parabolic cross-sectional shape corresponding to the mirror.

7. The module according to claim 1, wherein the pipe is a heat pipe.

8. The module according to claim 1, wherein the transparent top is formed with a curved shape.

9. The module according to claim 1, further comprising an anti-reflective coating on the transparent top.

10. The module according to claim 1, further comprising: a second bottom-facing planar wall; and a plurality of photovoltaic cells attached to the second bottom-facing planar wall.

11. The module according to claim 1, further comprising a plurality of photovoltaic cells attached to the top-facing planar wall.
